(19) United States
(12) Patent Application Publication
(10) Pub. No.: US 2026/0298274 A1
(43) Pub. Date: Oct. 1, 2026

(54) ATTACHMENT DEVICE FOR INSTALLING ON A STRUCTURE, AIRCRAFT OR SPACECRAFT, AND METHOD FOR MANUFACTURING AN ATTACHMENT DEVICE FOR INSTALLING ON A STRUCTURE

(71) Applicant: Airbus Operations GmbH, HAMBURG (DE)

(72) Inventors: Volker ROBRECHT, HAMBURG (DE); Matthias HEGENBART, HAMBURG (DE)

(21) Appl. No.: 19/572,053

(22) Filed: Mar. 19, 2026

(30) Foreign Application Priority Data
Mar. 27, 2025 (DE) 102025001078.8

(51) Int. Cl. F16B 19/04; C23C 14/06

(52) U.S. Cl. CPC F16B 19/04; C23C 14/0641; F16B 2019/045

(57) ABSTRACT

A fastening device for installation on a structure, in particular for the manufacture of an external structure of aircraft or spacecraft. The fastening device is a mechanical connecting element whose surface is made of a metallic material, and the mechanical connecting element has a head region with a coating that covers at least the surface of the head region. The coating comprises titanium aluminum nitride. Also an aircraft or spacecraft with such a fastening device and a method for manufacturing a fastening device for installation on a structure.

### CROSS-REFERENCES TO RELATED APPLICATIONS

This application claims the benefit of German Patent Application Number 102025001078.8, filed on Mar. 27, 2025, the entire disclosure of which is incorporated herein by way of reference.

### FIELD OF THE INVENTION

The present invention relates to a fastening device for installation on a structure, in particular for the manufacture of an external structure of aircraft or spacecraft. The present invention further relates to a method for manufacturing a fastening device for installation on a structure, in particular for manufacturing such a fastening device, as well as an aircraft or spacecraft.

### BACKGROUND OF THE INVENTION

The wettability and adhesion of liquid, semi-solid, and solid substances to metals and metal oxides depend strongly on the surface properties. This is of paramount importance when treating, applying, and adhering materials such as adhesives, paints, solders, sealants, or even biological tissue. Degreasing and other cleaning processes, as well as pickling, increase wettability and adhesion to a certain extent. Besides surface morphology, the chemistry of the surface and the appropriate surface roughness also influence the adhesion of the substances used for coating. Structuring the surface, preferably on multiple scales to increase the wetted area, as well as targeted chemical modification and the creation of thermodynamically stable oxide layers, positively impact the formation of durable adhesion.

A conventional method for manufacturing an aircraft's outer structure involves a grinding process of the fully assembled structure to prepare its surface, including the rivets, for painting. Due to manufacturing tolerances—both in rivet production and assembly—the rivets typically protrude or recess relative to the surface of the outer structure. Recessed rivets, in particular, present challenges in grinding the rivet head to ensure proper paint adhesion.

Surface treatment systems and paints for aircraft are optimized to adhere to an aluminum oxide layer through a primer and a final topcoat. The outer structure of aircraft is primarily made of aluminum, which forms the aluminum oxide layer through anodizing. The rivets attached to it, however, are rarely made of aluminum.

### SUMMARY OF THE INVENTION

An object of the present invention is to provide solutions for the production of a weather-resistant outer structure which is assembled from several segments using connectors.

According to one or more aspects of the present invention, this problem may be solved by the subject matter of one or more embodiments described herein.

According to a first aspect of the invention, a fastening device for installation on a structure, in particular for the manufacture of an external structure of aircraft or spacecraft, is provided. The fastening device comprises a mechanical connecting element whose surface is made of a metallic material. The mechanical connecting element has a head region. Furthermore, the fastening device comprises a coating that covers at least the surface of the head region, wherein the coating comprises titanium aluminum nitride.

According to a second aspect of the invention, an aircraft or spacecraft is provided which comprises an external structure to which a fastening device according to the first aspect of the invention is attached.

According to a third aspect of the invention, a method for manufacturing a fastening device for installation on a structure, in particular for manufacturing a fastening device according to the first aspect of the invention, is provided. The method comprises:
inserting a mechanical connecting element, the surface of which is made of a metallic material, into a coating chamber; and,
coating at least the surface of a head area of the mechanical connecting element with titanium aluminum nitride using a physical vapor deposition process.

One of the underlying ideas of the present invention is to provide a fastening device or connector with a special coating that exhibits excellent paint adhesion properties. The present invention ensures a continuous oxide layer independent of the base material. Furthermore, a method for the surface treatment of mechanical fasteners, which are essentially made of a metallic material, is provided to improve the adhesion of a paint or primer.

Titanium aluminum nitride can minimize potential deposits that might accumulate in common surface applications. Furthermore, titanium aluminum nitride offers excellent paint adhesion properties. The titanium aluminum nitride coating adheres to the surface of the metallic mechanical fastener through a strong molecular bond, forcing it to bond directly with the metallic surface as the substrate for the coating. In addition, the coating can improve the durability of the mechanical fastener by providing a harder, more protective surface. Due to the presence of titanium aluminum nitride, the coating exhibits ceramic properties. The chemical formula of titanium aluminum nitride is TiAlN.

The mechanical fastener can be, for example, a rivet, especially a blind rivet, or a screw. The head area corresponds, for example, to the part of the mechanical fastener that can be manipulated with a tool. The head area corresponds, for example, to the screw head of the screw or to the rivet head of the rivet.

In this way, the entire head area of the mechanical fastener can be coated with titanium aluminum nitride before the head area becomes partially accessible after installation and consequently may not be fully coated in the fastened state. In particular, coating the head area can provide protection against oxidation and other weathering in those zones where coating after fastening is not possible or is insufficient.

For example, the fastening device can be attached to the structure, such as the outer structure or skin of an aircraft or spacecraft. An advantage of the present invention is that, during the final painting of the outer structure, i.e., during the complete exterior painting, the phenomenon of paint adhesion loss on the fastening device can be prevented, since the paint adheres better to the coating of the fastening device than to the uncoated surface of the mechanical connecting element.

Advantageous embodiments and further developments result from the dependent claims relating back to the independent claims and from the description with reference to the figures.

According to one embodiment of the present invention, the coating comprises an oxidized layer arranged on an outer surface of the coating facing away from the mechanical fastener. The oxidized layer can resist further oxidation. This means that the mechanical fastener is protected from chemical erosion for a longer period of time. For example, the oxidized layer can withstand further oxidation at temperatures up to 800° C.

According to a further development of the present invention, the oxidized layer is formed from aluminum oxide. Thus, the outer surface of the coating can contain the same material as the outer skin of an aircraft or spacecraft in which the mechanical connecting element can be installed. Consequently, the outer surface of the coating exhibits, in particular, the same chemical material properties as the outer skin of the aircraft or spacecraft. The chemical formula of aluminum oxide is Al₂O₃.

If the coating, particularly the oxidized layer, wears down, the exposed titanium aluminum nitride on the outer surface can itself form new aluminum oxide to replace the loss of the oxidized layer due to wear. In this way, the oxidized layer can repair itself, ensuring that a continuous or full-surface oxidized layer is always present on the outer surface of the coating. The outer skin of the aircraft or spacecraft is essentially made of an aluminum structure.

For example, the metallic material of the mechanical fastener can contain or consist of a titanium alloy, a titanium alloy, a steel alloy, a nickel-chromium alloy, or an aluminum alloy. Optionally, the metallic material, i.e., the surface of the mechanical fastener without the coating, can have a surface finish, for example, cadmium, achieved through sulfuric acid anodizing or similar processes. The mechanical fastener can, for example, conform to EN 6114.

According to a further embodiment of the present invention, the coating has a thickness in the range of about (+\−10%) 1 μm to about 4 μm, in particular a thickness of about 3 μm. The coating can thus be very thin. In this way, the coating can conform to the contour of the surface of the mechanical connecting element.

According to a further embodiment of the present invention, the coating has a Vickers hardness in the range of about 2800 Hv to about 3200 Hv, in particular a Vickers hardness of about 3000 Hv. Thus, the coating provides robust protection for the surface it covers with an exceptionally hard and durable material. Furthermore, the coating can have a Rockwell hardness in the range of about 80 Rc to about 90 Rc, in particular a Rockwell hardness of about 85 Rc. Advantageously, the titanium aluminum nitride retains its hardness even at higher temperatures. Consequently, the coating can exhibit high temperature resistance.

According to a further embodiment of the present invention, the coating covers exclusively the surface of the head region. Thus, the coating cannot affect the surface of a shank and/or thread of the mechanical fastener. This means that the material properties of the shank and/or thread surface are retained and therefore differ from the material properties of the head region surface. In particular, the coating completely covers the surface of the head region.

According to a further embodiment of the present invention, the coating is produced by a physical vapor deposition process. For example, the physical vapor deposition process can comprise electron beam evaporation under vacuum.

According to a further embodiment of the present invention, the physical vapor deposition process comprises vacuum electron beam evaporation, which is carried out at a temperature of the mechanical fastener in the range of about 455° C. to about 500° C., particularly at a temperature of about 480° C. Electron beam evaporation can produce coatings that are very smooth and require no post-processing. The strongly adhesive layers deposited by electron beam evaporation can be highly resistant to oxidation, abrasive wear, and adhesive wear. For electron beam evaporation, the coating chamber can be evacuated. The temperature inside the coating chamber can correspond to the temperature of the mechanical fastener.

Before coating, the surface can be prepared appropriately. This means that, depending on the physical vapor deposition process, the surface can, for example, be cleaned to a high degree of purity, in particular by removing grease deposits.

The above embodiments and further developments can be combined with one another as appropriate. In particular, all features of the device are transferable to the associated method, and vice versa. Further possible embodiments, further developments, and implementations of the invention also include combinations of features of the invention described previously or subsequently with respect to the exemplary embodiments, even if not explicitly mentioned. In particular, those skilled in the art will also add individual aspects as improvements or additions to the respective basic form of the present invention.

### BRIEF DESCRIPTION OF THE DRAWINGS

The present invention is explained in more detail below with reference to exemplary embodiments and the accompanying figures. The figures show:

FIG. 1 shows a schematic representation of a fastening device for installation on a structure according to an embodiment of the invention;

FIG. 2 shows a schematic sectional view of a coating structure of a coating of the fastening device from FIG. 1 according to a further embodiment of the invention;

FIG. 3 shows a schematic side view of an aircraft according to a further embodiment of the invention; and

FIG. 4 shows a flowchart of a method for manufacturing a fastening device for installation on a structure, in particular for manufacturing a fastening device according to FIG. 1, according to a further embodiment of the invention.

### DETAILED DESCRIPTION OF THE PREFERRED EMBODIMENTS

In the figures of the drawing, identical, functionally equivalent and similarly acting elements, features and components-unless otherwise stated-are each provided with the same reference symbols.

Although specific embodiments and further developments are presented and described herein, the person skilled in the art will prefer that a multitude of alternative and/or similar embodiments can replace the specific embodiments presented and described without departing from the scope of the present invention. This application is intended to generally cover all variations or modifications of the specific embodiments described herein.

The accompanying figures are intended to provide a further understanding of embodiments of the invention and serve, in conjunction with the description, to explain the principles and concepts of the invention. Other embodiments and many of the advantages mentioned will become apparent with regard to the drawings. The drawings are to be understood merely as schematic drawings, and the elements of the drawings are not necessarily shown to scale. Directional terminology such as “above”, “below”, “left”, “right”, “over”, “under”, “horizontal”, “vertical”, “front”, “back” and similar terms are used for explanatory purposes only and do not serve to restrict the general public to specific configurations as shown in the figures.

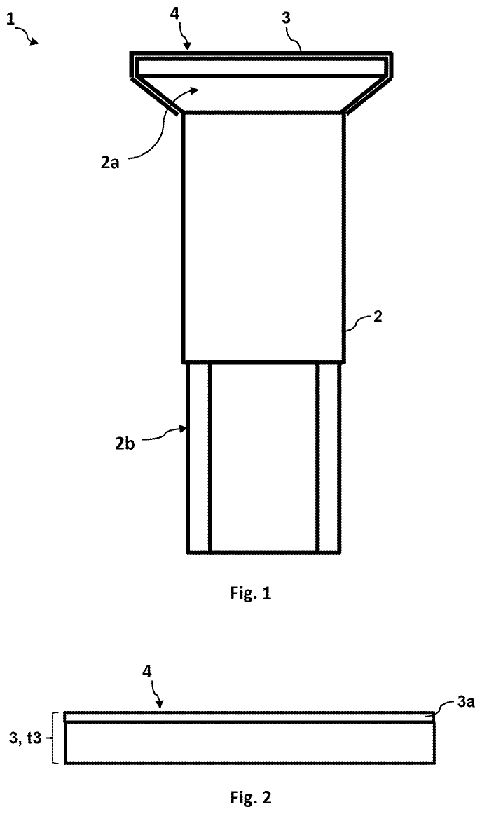

FIG. 1 shows a schematic representation of a fastening device 1 for installation on a structure according to an embodiment of the invention.

The fastening device 1 includes, by way of example, a mechanical connecting element 2 and a coating 3.

One surface of the mechanical connecting element 2 is made of a metallic material. For example, the metallic material of the mechanical connecting element 2 can contain or consist of a titanium alloy, a titanium alloy, a steel alloy, a nickel-chromium alloy, or an aluminum alloy.

The mechanical fastener 2 has a head region 2a. The mechanical fastener 2 can, for example, be designed as a rivet, as shown in FIG. 1. The head region 2a corresponds, for example, to the part of the mechanical fastener 2 that can be manipulated with a tool. Here, the head region 2a corresponds to the rivet head of the rivet 2. Furthermore, the mechanical fastener 2, designed as a rivet, has a cylindrical shank with a thread 2b. The mechanical fastener 2 shown in FIG. 1 is commonly referred to as a rivet in the aerospace industry, although this designation does not exclude classic rivets, in particular blind rivets.

The coating 3 covers at least the surface of the head region 2a, and the coating 3 comprises titanium aluminum nitride. The titanium aluminum nitride coating 3 adheres to the surface of the metallic mechanical fastener 2 by a strong molecular bond, which forces it to bond directly with the metallic surface as a substrate for the coating 3. The coating 3 can exhibit a Vickers hardness in the range of about 2800 Hv to about 3200 Hv, particularly a Vickers hardness of about 3000 Hv. According to an alternative classification, the coating 3 can exhibit a Rockwell hardness in the range of about 80 Rc to about 90 Rc, particularly a Rockwell hardness of about 85 Rc. Advantageously, the titanium aluminum nitride retains its hardness even at higher temperatures.

The coating 3 can cover only the surface of the head region 2a, as illustrated by way of example in FIG. 1. Thus, the coating 3 cannot affect the surface of the shank and thread 2b of the mechanical connecting element 2. This means that the material properties of the surface of the shank and thread 2b are retained and therefore differ from the material properties of the surface of the head region 2a. In particular, the coating 3 completely covers the surface of the head region 2a.

An outer surface 4 of the coating 3 faces away from the mechanical connecting element 2.

For example, the coating 3 can be produced by a physical vapor deposition (PVD) process. Preferably, the PVD process can include electron beam evaporation under vacuum. The PVD process provides an environmentally friendly manufacturing method for coating, in which the titanium aluminum nitride is converted from a condensed solid to a vapor and then condenses back into a thin film on the surface.

FIG. 2 shows a schematic sectional view of a coating structure of a coating 3 of the fastening device from FIG. 1 according to a further embodiment of the invention.

The coating 3 essentially comprises the features of the coating 3 from FIG. 1, wherein the coating 3 shown here in FIG. 2 has an oxidized layer 3a. The oxidized layer 3a is located on the outer surface 4 of the coating 3 facing away from the mechanical connecting element 2. The oxidized layer 3a can resist further oxidation. This means that the mechanical connecting element 2 is protected from chemical erosion for a longer period of time. For example, the oxidized layer 3a can withstand further oxidation at temperatures up to 800° C.

In particular, the oxidized layer 3a is composed of aluminum oxide. If the coating 3, especially the oxidized layer 3a, becomes worn, the exposed titanium aluminum nitride on the outer surface 4 can itself form new aluminum oxide to replace any loss of the oxidized layer 3a due to wear. In this way, the oxidized layer 3a can repair itself, ensuring that a continuous or full-surface oxidized layer 3a is always present on the outer surface 4 of the coating 3.

For example, the coating 3 can have a thickness t3 in the range of about 1 μm to about 4 μm, in particular a thickness t3 of about 3 μm. In this way, the coating 3 can assume a contour of the surface of the mechanical connecting element 2.

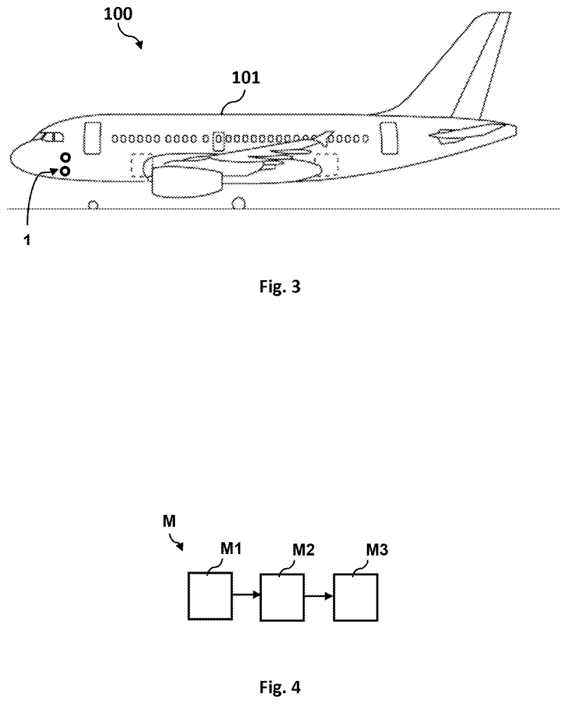

FIG. 3 shows a schematic side view of an aircraft 100 according to a further embodiment of the invention.

The aircraft 100 comprises an outer structure 101, or outer skin, which is shown here by way of example on a fuselage, wings, and a tail assembly of the aircraft 100. The outer structure 101 contains, in particular, a plurality of sections that are assembled by means of at least one fastening device, or connector, 1. Two fastening devices 1 are illustrated by way of example in FIG. 3.

The at least one fastening device 1 is, for example, installed on an outer surface of the outer structure 101. Each installed fastening device 1 essentially comprises the features of the fastening device shown in FIG. 1 or 2.

FIG. 4 shows a flowchart of a method M for manufacturing a fastening device for installation on a structure, in particular for manufacturing a fastening device 1 according to FIG. 1, according to a further embodiment of the invention.

The process M includes, for example, the insertion M1 of a mechanical connecting element 2, the preparation M2 of a surface and the coating M3.

In step M1, the mechanical fastener 2 is placed in a coating chamber, wherein one surface of the mechanical fastener 2 is made of a metallic material. For example, the metallic material of the mechanical fastener 2 can be a titanium alloy, a titanium alloy, a steel alloy, a nickel-chromium alloy, or an aluminum alloy. The mechanical fastener 2 has a head region 2a. The mechanical fastener 2 can be designed, for example, as a rivet, in particular a blind rivet, or as a screw. The head region 2a corresponds, for example, to the part of the mechanical fastener 2 that can be manipulated with a tool. The head region 2a corresponds, for example, to the screw head of the screw or to the rivet head of the rivet.

In the optional step M2, the surface can be prepared appropriately. This means that, depending on the subsequent physical vapor deposition process, the surface can, for example, be cleaned to a high degree of purity, in particular by removing grease deposits. Optionally, an adhesion promoter can be applied to the surface.

In step M3, at least the surface of the head region 2a of the mechanical fastener 2 is coated with titanium aluminum nitride using a physical vapor deposition (PVD) process. Specifically, the PVD process comprises vacuum electron beam evaporation, which is carried out at a temperature of the mechanical fastener 2 in the range of about 455° C. to about 500° C., particularly at a temperature of about 480° C. Electron beam evaporation can produce coatings that are very smooth and require no post-processing. The strongly adhering coating layers deposited by electron beam evaporation can be highly resistant to oxidation, abrasive wear, and adhesive wear. The coating chamber can be evacuated for electron beam evaporation. The temperature inside the coating chamber can correspond to the temperature of the mechanical fastener 2. The physical vapor deposition process can be set up such that only the surface of the head region 2a is coated with titanium aluminum nitride.

The process steps described above can preferably be carried out in the order in which they are mentioned or numbered, but are not limited to this order.

In the preceding detailed description, various features have been summarized in one or more examples to improve the clarity of the presentation. However, it should be clear that the above description is merely illustrative and in no way limiting. It serves to cover all alternatives, modifications, and equivalents of the various features and embodiments. Many other examples will be immediately and directly clear to the person skilled in the art based on their technical knowledge, given the above description.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

### REFERENCE NUMBER LIST

1 fastening device
2 mechanical connecting element
2a head area of the mechanical connecting element
2b thread of the mechanical connecting element
3 coating
3a oxidized layer of the coating
t3 coating thickness
4 outside
100 aircraft
101 exterior structure
M procedure
M1 insertion of a mechanical connecting element
M2 preparing the surface
M3 coating

Claimed is:

1. A fastening device for installation on a structure, the fastening device comprising:
a mechanical connecting element having a surface made of a metallic material, wherein the mechanical connecting element has a head region; and
a coating covering at least the surface of the head region, wherein the coating comprises titanium aluminum nitride.

2. The fastening device according to claim 1, wherein the coating has an oxidized layer arranged on an outer surface of the coating facing away from the mechanical connecting element.

3. The fastening device according to claim 2, wherein the oxidized layer comprises aluminum oxide.

4. The fastening device according to claim 1, wherein the coating has a thickness in a range of about 1 μm to about 4 μm.

5. The fastening device according to claim 1, wherein the coating has a Vickers hardness in a range of about 2800 Hv up to about 3200 Hv.

6. The fastening device according to claim 1, wherein the coating only covers the surface of the head region.

7. The fastening device according to claim 1, wherein the coating is produced by a physical vapor deposition process.

8. An aircraft or spacecraft comprising:
an external structure; and,
at least one fastening device according to claim 1 attached to the external structure.

9. A method for manufacturing a fastening device, the method comprising:
inserting a mechanical connecting element having a surface made of a metallic material into a coating chamber; and
coating at least the surface of a head region of the mechanical connecting element with titanium aluminum nitride by a physical vapor deposition process.

10. The method according to claim 9, wherein the physical vapor deposition process comprises electron beam evaporation under vacuum carried out with a temperature of the mechanical connecting element in a range of about 455° C. to about 500° C.
